(19) United States
(12) Patent Application Publication
(10) Pub. No.: US 2010/0066441 A1
(43) Pub. Date: Mar. 18, 2010

(54) MOS with reverse current limiting function and a voltage conversion circuit using the same

(76) Inventor: Zhong-Wei Liu, Wuxi (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 12/382,761

(22) Filed: Mar. 24, 2009

(30) Foreign Application Priority Data
Sep. 17, 2008 (TW) 97135541

(51) Int. Cl. G05F 3/04; H01L 29/78

(52) U.S. Cl. 327/543; 257/355; 257/E29.255; 257/412

(57) ABSTRACT

A MOS with reverse current limiting function and a voltage conversion circuit using the same is disclosed which employs a resistance unit coupled between a base and a first source/drain of a metal oxide semiconductor (MOS). When a reverse current occurs, a reverse current passing through a body diode of the MOS is limited to prevent the MOS from being burned out due to overheating. Moreover, the voltage level of the base is equal to the voltage level of the first source/drain, such that the Rds (on) of the MOS can be reduced. Therefore, a converter with the disclosed MOS may provide a higher conversion efficiency.

### BACKGROUND OF THE INVENTION

1. Field of the invention

The present invention relates to a metal oxide semiconductor (MOS) and a voltage conversion circuit using the MOS, and more particularly to a MOS with reverse current limiting function and a voltage conversion circuit using the MOS.

2. Description of Related Art

At present, most power supply circuits adopt a metal oxide semiconductor field effect transistor (MOSFET) as the control switch for power conversions. With reference to FIG. 1A for a schematic view of a traditional structure of an N-type MOSFET and its equivalent circuit diagram, the drawing on the right side of FIG. 1A shows a cross-sectional view of the N-type MOSFET. High-concentration N-type ions are implanted into two regions of a P-type substrate Psub to form a source S and a drain D respectively. A silicon dioxide layer (indicated by the section lined region in FIG. 1A) and a gate G are formed sequentially between the source S and the drain D. By controlling the voltage of the gate G, a channel can be formed between the source S and drain D. Since the substrate Psub is a P-type substrate, and the source S and the drain D are N-type source and drain, two diodes (which is called as body diodes) are formed between the substrate Psub and the source S and between the substrate Psub and the drain D respectively. To prevent the two diodes from being conducted inappropriately, it is necessary to keep the voltage level of the substrate Psub lower than the voltage levels of the source S and the drain D. Thus, the high-concentration P-type ions are implanted into a region of the substrate Psub to form a base B, and the base B is grounded for preventing from the problem. The circuit diagram on the left side of FIG. 1A shows an equivalent circuit diagram of this N-type MOSFET.

Although the aforementioned MOSFET can prevent the body diode from being conducted inappropriately, a higher power loss will result since the lower the voltage level of the base B, the higher is the threshold voltage of the MOSFET and the higher is the drain-to-source resistance Rds (on).

With reference to FIG. 1B for a schematic view of a traditional structure of a P-type MOSFET and its equivalent circuit diagram, the drawing on the right side of FIG. 1B shows a cross-sectional view of the P-type MOSFET. An N-well is formed on a substrate Psub. High-concentration P-type ions are implanted into two regions of the N-well to form a source S and a drain D respectively. A silicon dioxide layer (indicated by the section lined region in FIG. 1B) and a gate G are formed sequentially between the source S and the drain D. In addition, high-concentration N-type ions are implanted into a region of the N-well to form a base B, and the base B is coupled to a voltage source VCC, such that diodes between the N-well and the source S and between the N-well and the drain D are reverse-biased to prevent the diode from being conducted inappropriately. The circuit diagram on the left side of FIG. 1B shows an equivalent circuit diagram of this P-type MOSFET.

With reference to FIG. 2A for a schematic view of a traditional structure of another N-type MOSFET and its equivalent circuit diagram, the drawing on the right side of FIG. 2A shows a cross-sectional view of the N-type MOSFET. A DNwell and a P-well are formed sequentially on a substrate Psub. High-concentration N-type ions are implanted into two regions of the P-well to form a source S and a drain D respectively. A silicon dioxide layer (indicated by the section lined region in FIG. 2A) and a gate G are formed sequentially between the source S and the drain D. High-concentration P-type ions are implanted into a region of a P-well to form a base B. In the N-type MOSFET, the source S is coupled to the base B, so as to lower a threshold voltage and a drain-to-source resistance Rds (on) thereof. Now, the substrate Psub is grounded, and the DNwell is coupled to a voltage source VCC, so that a diode between the substrate Psub and the DNwell is reverse-biased to prevent the diode from being conducted inappropriately. In addition, a body diode D1 is formed between the base B and the drain D. The circuit diagram on the left side of FIG. 2A shows an equivalent circuit diagram of this N-type MOSFET.

With reference to FIG. 2B for a schematic view of a traditional structure of another P-type MOSFET and its equivalent circuit diagram, the drawing on the right side of FIG. 2B shows a cross-sectional view of the P-type MOSFET. A DNwell and an N-well are formed sequentially on a substrate Psub, and then high-concentration P-type ions are implanted into two regions of the N-well to form a source S and a drain D respectively. A silicon dioxide layer (indicated by the section lined region in FIG. 2B) and a gate G are formed sequentially between the source S and the drain D. High-concentration N-type ions are implanted into a region of the N-well to form a base B. In the P-type MOSFET, the source S is coupled to the base B, so as to lower a threshold voltage and a drain-to-source resistance Rds (on) thereof. Now, the substrate Psub is grounded to assure a diode between the substrate Psub and the DNwell is reverse-biased to prevent the diode from being conducted inappropriately. In addition, a body diode D2 is formed between the base B and the drain D. The circuit diagram on the left side of FIG. 2B shows an equivalent circuit diagram of this P-type MOSFET.

With reference to FIG. 2C for a schematic circuit diagram of a low dropout regulator (LDO) using the N-type MOSFET as depicted in FIG. 2A, the low dropout regulator comprises an N-type MOSFET 5, a control unit 10, a feedback circuit 20, and a load 30. A drain D of the N-type MOSFET 5 is coupled to an input source Vin, and a source S of the N-type MOSFET 5 is coupled to a load 30 for supplying an output voltage Vout. The feedback circuit 20 is coupled to a source S of the N-type MOSFET 5 to generate an output voltage feedback signal. The control unit 10 adjusts the gate voltage of the N-type MOSFET 5 according to the output voltage feedback signal, such that the output voltage Vout falls within a predetermined voltage value for the load 30 operating. However, if there is any abnormal condition of the low dropout regulator resulting in a sudden increase of the voltage level of the source S higher than the voltage level of the drain D, then the body diode D1 will be forward-biased to conduct an reverse current Ir even when the control unit 10 turns off the N-type MOSFET 5. After the body diode D1 is conducted, the voltage and current are in an exponential relation, and thus a considerably large reverse current Ir will pass through the body diode D1 and result in an easy burnout of the N-type MOSFET 5. Similarly, the P-type MOSFET as shown in FIG. 2B will be damaged easily if the body diode D2 is forward-biased to conduct an reverse current Ir when the voltage level of the source S is decreased suddenly below the voltage level of the drain D.

### SUMMARY OF THE INVENTION

In view of excessively high drain-to-source resistance Rds (on) of the aforementioned MOSFET or the easy burnout caused by reverse current, the present invention installs a resistance unit between a base and a first source/drain of a MOS, such that when an reverse current occurs, the reverse current passing through a body diode is limited to prevent the MOS from being burned due to overheat. Moreover, because the voltage levels of the base and the first source/drain of the MOS are equal, the drain-to-source resistance Rds (on) of the MOS is relatively small, and further the MOS incurs a low power loss to provide higher-conversion efficiency to a conversion circuit of the MOS.

To achieve the foregoing advantages, the present invention provides a MOS with a limited reverse current, comprising a MOS and a current-limit resistance unit. The MOS includes a first source/drain, a second source/drain, a gate, and a base, wherein the first source/drain is coupled to the base and a diode is formed between the base and the second source/drain. The current-limit resistance unit is coupled between the first source/drain and the base for limiting a current passing through the diode.

The present invention also provides a voltage conversion circuit comprising a switch module, a feedback circuit and a control unit, for converting an input voltage into an output voltage and supplying the output voltage to a load. The switch module is coupled to the input voltage for transmitting an electric power from the input voltage to the load, and the switch module includes at least one MOS with reverse current limiting function. Each MOS with a limited reverse current comprises a MOS and a current-limit resistance unit. The MOS comprises a first source/drain, a second source/drain, a gate, and a base, wherein the first source/drain is coupled to the base and a diode is formed between the base and the second source/drain. The current-limit resistance unit is coupled between the first source/drain and the base for limiting a current passing through the diode. The feedback circuit is coupled to the load for outputting a feedback signal according to the status of the load. The control unit is coupled to the switch module and the feedback circuit for controlling the status of the switch module according to the feedback signal.

The above and other objects, features, and advantages of the present invention will become apparent from the following detailed description taken with the accompanying drawing.

### BRIEF DESCRIPTION OF THE DRAWINGS

FIG. 1A is a schematic view of a traditional structure of an N-type MOSFET and its equivalent circuit diagram;

FIG. 1B is a schematic view of a traditional structure of a P-type MOSFET and its equivalent circuit diagram;

FIG. 2A is a schematic view of a traditional structure of another N-type MOSFET and its equivalent circuit diagram;

FIG. 2B is a schematic view of a traditional structure of another P-type MOSFET and its equivalent circuit diagram;

FIG. 2C is a schematic circuit diagram of a low dropout regulator using the N-type MOSFET as depicted in FIG. 2A;

FIG. 3A is a schematic view of a structure of an N-type MOSFET and its equivalent circuit diagram in accordance with a preferred embodiment of the present invention;

FIG. 3B is a schematic circuit diagram of a low dropout regulator using the MOSFET as depicted in FIG. 3A;

FIG. 3C is a schematic circuit diagram a voltage conversion circuit using the MOS of the present invention;

FIG. 4 is a schematic view of a structure of a P-type MOSFET and its equivalent circuit diagram in accordance with another preferred embodiment of the present invention;

FIG. 5 is a schematic view of a structure of an N-type double-diffused MOS and its equivalent circuit diagram in accordance with a preferred embodiment of the present invention; and

FIG. 6 is a schematic view of a structure of a P-type trench MOS and its equivalent circuit diagram in accordance with a preferred embodiment of the present invention.

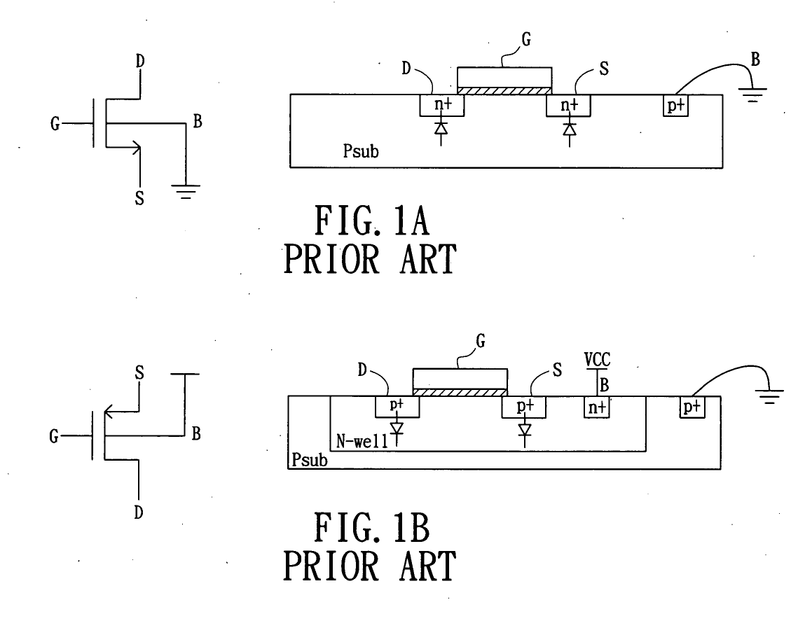

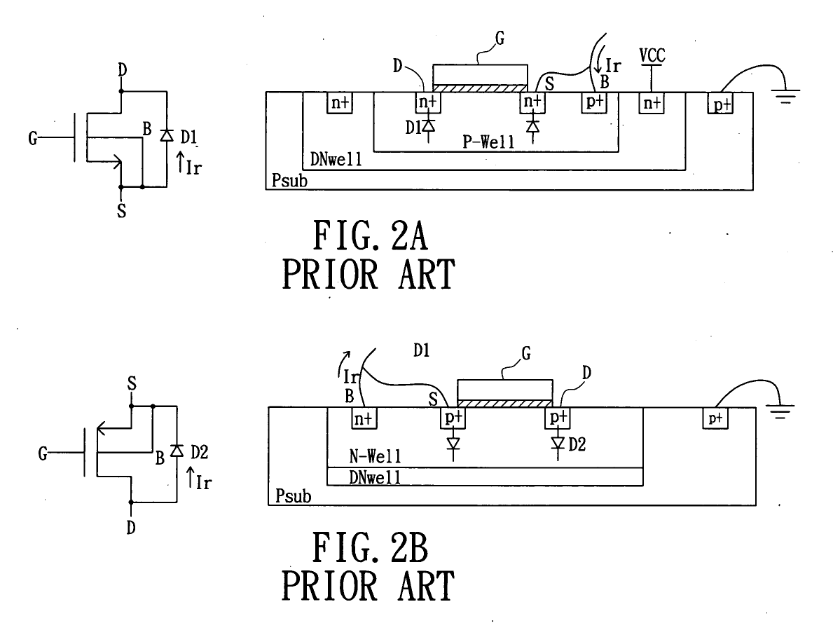

### DETAILED DESCRIPTION OF THE PREFERRED EMBODIMENTS

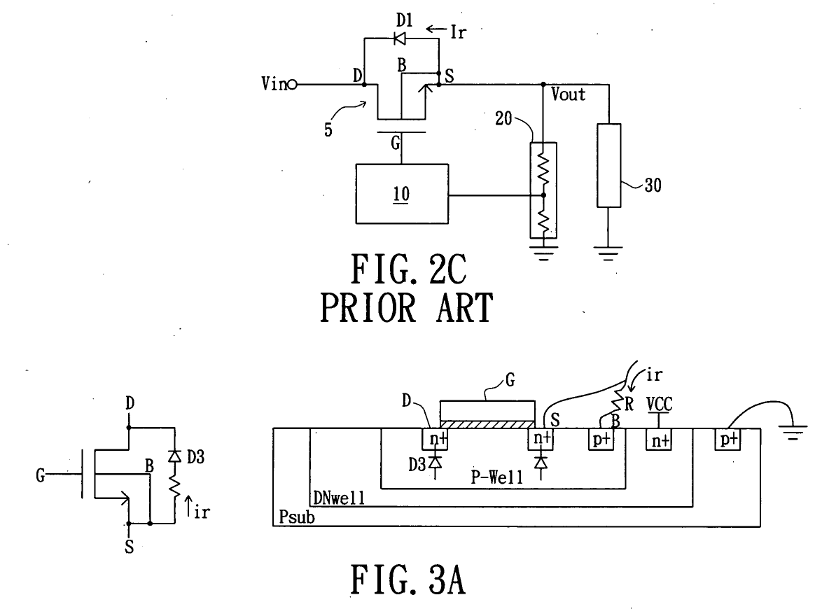

With reference to FIG. 3A for a schematic view of a structure of an N-type MOSFET and its equivalent circuit diagram in accordance with a preferred embodiment of the present invention, the drawing on the right side of FIG. 3A shows a cross-sectional view of the N-type MOSFET. A DNwell and a P-well are formed sequentially on a substrate Psub. High-concentration N-type ions are implanted into two regions of the P-well to form a source S and a drain D respectively. A silicon dioxide layer (indicated by the section lined region in FIG. 3A) and a gate G are formed sequentially between the source S and the drain D. High-concentration P-type ions are implanted into a region of the P-well to form a base B. In the N-type MOSFET, the source S and the base B are coupled through a resistance unit R, such that the voltage levels of the source S and the base B are substantially equal to provide a low threshold voltage and a low drain-to-source resistance Rds (on). Meanwhile, a body diode D3 is formed between the base B and the drain D and a reverse-current ir passing through the body diode D3 can be limited by means of the resistance unit R. The current-limit resistance unit R forms simultaneously when a gate G at the MOS is formed, e.g.: forming a polycrystalline silicon layer onto the silicon dioxide layer and defined by a photo-mask. The circuit diagram on the left side of FIG. 3A shows an equivalent circuit diagram of this N-type MOSFET.

With reference to FIG. 3B a schematic circuit diagram of a low dropout regulator using the MOSFET as depicted in FIG. 3A, the low dropout regulator comprises a MOSFET 15 used as a switch module, a control unit 10, a feedback circuit 20 and a load 30. A drain D of the MOSFET 15 is coupled to an input source Vin, and a source S of the MOSFET 15 is coupled to the load 30 for transmitting the electric power of the input voltage Vin to the load 30 and supplying an output voltage Vout. The feedback circuit 20 is coupled to the source S of the MOSFET 15 for generating an output voltage feedback signal. The control unit 10 adjusts a gate voltage of the MOSFET 15 according to the output voltage feedback signal such that the output voltage Vout falls within a predetermined voltage value for the load 30 operating. If there is any abnormal condition of the low dropout regulator resulting in a sudden increase of the voltage level of the source S higher than the voltage level of the drain D, then the body diode D3 will be forward-biased to conduct a reverse current ir. Since the reverse current ir passes through the resistance unit R and the body diode D3, the voltage-current relation is close to a linear relation, so that the reverse current ir will not be too large and so to prevent the MOSFET 15 from being burned.

In addition to the application for a low dropout regulator, the MOS of the present invention can also be applied in other voltage conversion circuits. With reference to FIG. 3C for a schematic circuit diagram of a voltage conversion circuit using the MOS of the present invention, the voltage conversion circuit is provided for converting an input voltage Vin into an output voltage Vout to be supplied to a load 30, and the voltage conversion circuit comprises a switch module, a feedback circuit 20, a conversion module, and a control unit 50. The switch module comprises two metal oxide semiconductors (MOS) 15, 55, wherein the MOS 15 is the MOS of the present invention and MOS 55 can be a traditional MOSFET. The switch module is coupled to the input voltage Vin for transmitting an electric power of the input voltage Vin to the load 30. The feedback circuit 20 is coupled to the load 30 for outputting a feedback signal Vfb according to a-status of the load 30. For different applications, the status of the load 30 can be either the voltage value applied to a load or the current value passing through the load 30. In this preferred embodiment, the feedback circuit 20 is a voltage divider for dividing the voltage value of the load as a feedback signal Vfb. The control unit 50 is coupled to the switch module and the feedback circuit 20 for controlling the ON or OFF status of the switch module according to the feedback signal Vfb. The conversion module is coupled to the switch module and the load 30 for converting the electric power of the input voltage Vin transmitted through the switch module into an output voltage Vout, and the conversion module of this preferred embodiment comprises an inductor L and a capacitor C, and an end of the inductor L is coupled to a connecting point of the MOS 15, 55 of the switch module, and the capacitor C is coupled to the other end of the inductor L and grounded. In actual applications, the conversion module may include a transformer, or a conversion component capable of storing and discharging energy.

The MOS of the voltage conversion circuit can be coupled to the control unit externally, or manufactured and packaged in a same fabrication process (built in the same die), or packaged into a single package in the form of a multi-chip package.

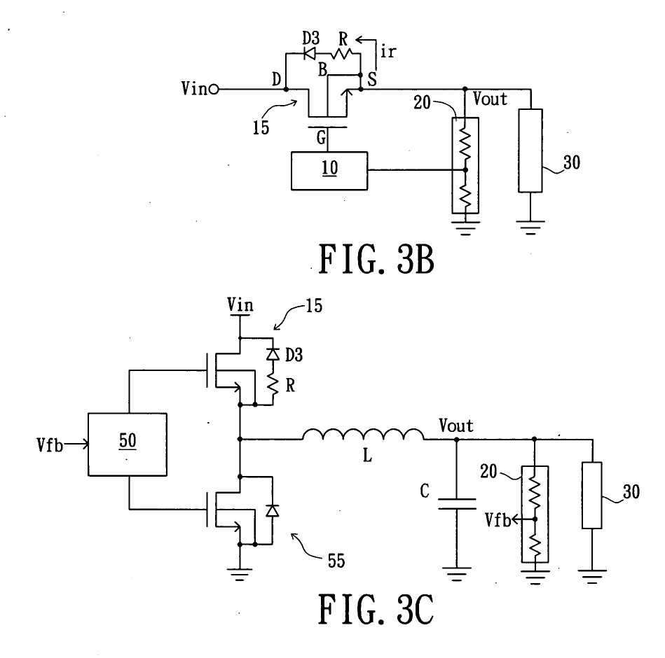

In addition, the present invention can be applied to a P-type MOS. With reference to FIG. 4 for a schematic view of a structure of a P-type MOSFET and its equivalent circuit diagram in accordance with another preferred embodiment of the present invention. A DNwell and an N-well are formed sequentially on a substrate Psub. High-concentration P-type ions are implanted into two regions of the N-well to form a source S and a drain D respectively. A silicon dioxide layer (indicated by the section lined region in FIG. 4) and a gate G are formed sequentially between the source S and the drain D, and high-concentration N-type ions are implanted into a region of the N-well to form a base B. In this P-type MOSFET, the source S and the base B are coupled through a resistance unit R, such that the voltage levels of the source S and the base B are substantially equal to obtain a lower threshold voltage and a lower drain-to-source resistance Rds (on). In the meantime, a body diode D4 is formed between the base B and the drain D and a reverse current ir passing through the body diode D4 can be limited through the resistance unit R. The circuit diagram on the left side of FIG. 4 shows an equivalent circuit diagram of this P-type MOSFET.

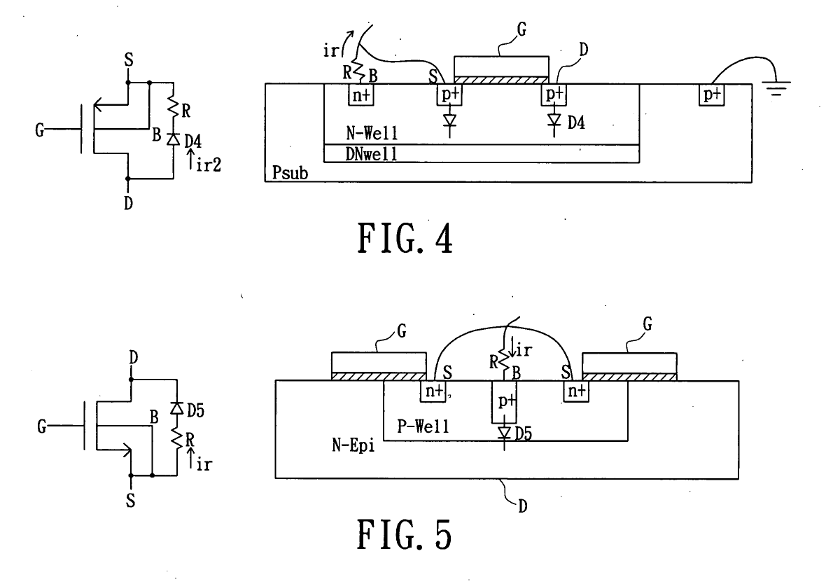

The present invention can be applied to other types of MOS for limiting a reverse current so as to prevent the MOS from being burned by a too-large reverse current. With reference to FIG. 5 for a schematic view of a structure of an N-type double-diffused MOS and its equivalent circuit diagram in accordance with a preferred embodiment of the present invention, the drawing on the right side of FIG. 5 shows a cross-sectional view of the N-type double-diffused MOS, wherein a P-well is formed on an N-type epitaxial layer (N-Epi), and high-concentration N-type ions are implanted into the regions on both lateral sides of the P-well to form two sources S, and high-concentration P-type ions are implanted into a region between the two sources S to form a base B. A silicon dioxide layer (indicated by the section lined region in FIG. 5) and a gate G are formed sequentially on both lateral sides of the P-well. The N-epitaxial layer Epi serves as a drain D of the N-type double-diffused MOS. In this MOSFET, the source S and the base B are coupled through a resistance unit R, such that the voltage levels of the source S and the base B are substantially equal to obtain a lower threshold voltage and a lower drain-to-source resistance Rds (on). In the meantime, a body diode D5 is formed between the base B and the drain D and a reverse current ir passing through by the body diode D5 can be limited by the resistance unit R. The circuit diagram on the left side of FIG. 5 shows an equivalent circuit diagram of this N-type double-diffused MOS.

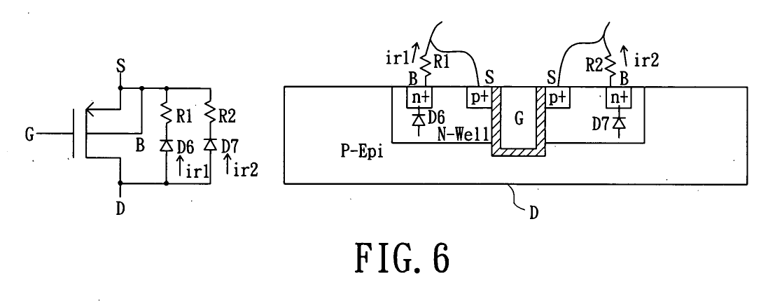

With reference to FIG. 6 for a schematic view of a structure of a P-type trench MOS and its equivalent circuit diagram in accordance with a preferred embodiment of the present invention, the drawing on the right side of FIG. 6 is a cross-sectional view of the P-type trench MOS. A n N-well is formed on the P-type epitaxial layer P-Epi, and a trench is etched at the middle of the N-well to expose the P-type epitaxial layer P-Epi. A silicon dioxide layer (indicated by the section lined region in FIG. 6) and a gate G are formed sequentially in the trench. High-concentration P-type ions are implanted into regions on both lateral sides of the trench to form two sources S, and high-concentration N-type ions are implanted into regions on both lateral sides of the N-well to form two bases B. The P-type epitaxial layer P-Epi serves as a drain D of the P-type trench MOS. In this MOSFET, the two bases B are coupled to the two sources S through the resistance unit R1, R2 respectively, such that the voltage levels of the two sources S and the two bases B are substantially equal to obtain a lower threshold voltage and a lower drain-to-source resistance Rds (on). In the meantime, two body diodes D6, D7 are formed between the two bases B and the drain D and reverse currents ir1, ir2 respectively passing through the two body diodes D6, D7 can be limited by two resistances unit R1, R2. The circuit diagram on the left side of FIG. 6 shows an equivalent circuit diagram of this P-type trench MOS.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A metal oxide semiconductor (MOS) with reverse current limiting function, comprising:
a MOS, having a first source/drain, a second source/drain, a gate, and a base, wherein the first source/drain is coupled to the base and a diode is formed between the base and the second source/drain; and
a current-limit resistance unit, coupled between the first source/drain and the base, for limiting a current passing through the diode.

2. The MOS with reverse current limiting function of claim 1, wherein the current-limit resistance unit is made of polycrystalline silicon.

3. The MOS with reverse current limiting function of claim 1, wherein the MOS is a metal oxide semiconductor field effect transistor (MOSFET), a P-type trench MOS, or an N-type double-diffused MOS.

4. A voltage conversion circuit, for converting an input voltage into an output voltage and supplying the output voltage to a load, comprising:
a switch module, coupled to the input voltage, for transmitting the electric power from the input voltage to the load, and the switch module comprising at least one MOS with reverse current limiting function, each MOS with reverse current limiting function comprising:
a MOS, having a first source/drain, a second source/drain, a gate, and a base, wherein the first source/drain is coupled to the base and a diode is formed between the base and the second source/drain; and
a current-limit resistance unit, coupled between the first source/drain and the base, for limiting a current passing through the diode.
a feedback circuit, coupled to the load, for outputting a feedback signal according to the status of the load; and
a control unit, coupled to the switch module and the feedback circuit, for controlling the status of the switch module according to the feedback signal.

5. The voltage conversion circuit of claim 4, wherein the voltage conversion circuit is a low dropout regulator.

6. The voltage conversion circuit of claim 5, wherein the current-limit resistance unit is made of polycrystalline silicon.

7. The voltage conversion circuit of claim 5, wherein the MOS is a MOSFET, a P-type trench MOS, or an N-type double-diffused MOS.

8. The voltage conversion circuit of claim 4, further comprising a conversion module coupled to the switch module and the load for converting the input voltage into the output voltage.

9. The voltage conversion circuit of claim 8, wherein the current-limit resistance unit is made of polycrystalline silicon.

10. The voltage conversion circuit of claim 8, wherein the MOS is a MOSFET, a P-type trench MOS or an N-type double-diffused MOS.
